(19) United States
(12) Patent Application Publication
(10) Pub. No.: US 2010/0289519 A1
(43) Pub. Date: Nov. 18, 2010

(54) CIRCUIT FOR DETECTING FAULTY DIODE

(75) Inventor: CHI-FENG HUANG, Hsinchu (TW)

Correspondence Address: WPAT, PC;INTELLECTUAL PROPERTY ATTORNEYS, 7225 BEVERLY ST., ANNANDALE, VA, 22003, US

(73) Assignee: ENE TECHNOLOGY INC., Hsinchu (TW)

(21) Appl. No.: 12/632,126

(22) Filed: Dec. 7, 2009

(30) Foreign Application Priority Data
May 15, 2009 (TW) 098116230

(51) Int. Cl. G01R 31/26; G01R 19/00

(52) U.S. Cl. 324/767; 324/123 R

(57) ABSTRACT

A circuit for detecting faulty diode comprises a diode having an anode connected to a voltage supply; a resistor having a first end connected to a cathode of the diode; a transistor having a drain connected to a second end of the resistor and a source that is grounded; a differential amplifier having a positive terminal connected to the drain of the transistor, a negative terminal connected to a reference voltage input terminal for receiving a reference voltage, and an output terminal connected to a gate of the transistor; and a buffer having an input terminal connected to the gate of the transistor, and a signal output terminal used to output a faulty signal.

### FIELD OF THE INVENTION

The present invention relates to a detecting circuit, and more particularly to a circuit for detecting faulty diode.

### BACKGROUND OF THE INVENTION

FIG. 1 illustrates a conventional circuit for detecting faulty diode disclosed in U.S. Pat. No. 6,225,912, issued in May 1, 2001. The circuit for detecting faulty diode is applied in a light-emitting diode (LED) array, which comprises a plurality of LEDs 1, a plurality of comparators 3 and a plurality of transistors 2. Wherein each of the LEDs 1 is associated with a transistor 2 and a comparator 3; each of the LEDs 1 has an anode parallel connected to a driving voltage supply terminal Vₐ (+) and a cathode electrically connected to the negative terminal of the corresponding comparator 3 and the drain of the corresponding transistor 2; all positive terminals of the comparators 3 are connected to a reference voltage input terminal; each gate of the transistors 2 is connected to a turning-on signal input terminal; each source of the transistors 2 is connected to a driving voltage supply terminal V_{b} (−); and each comparator 3 has a output terminal connected to a particular faulty signal output terminal.

Assuming that a forward bias of the LED 1 is V_{f}, thereby the comparators 3 corresponding to the reference voltage input terminal can receive a reference voltage. When the reference voltage is less than Vₐ but greater than (Vₐ−V_{f}), a process for detecting fault of short circuit can be conducted; otherwise when the reference voltage is less than (Vₐ−V_{f}), a process for detecting fault of open circuit can be conducted.

To the process for detecting fault of short circuit, for example, while the LED 1 is operated normally, the voltage applied to the negative terminal of the corresponding comparators 3 is (Vₐ−V_{f}), and the reference voltage received by the positive terminal of the corresponding comparator 3 is in the range between Vₐ and (Vₐ−V_{f}). It means that, when the output of the faulty signal output terminal corresponding to the comparator 3 is maintained in a high level (H), which indicates that the LED 1 is operated in a normal situation. On the contrary, while the LED 1 is shorted, the voltage applied to the negative terminal of the corresponding comparator 3 is Vₐ, and the reference voltage received by the positive terminal of the comparator 3 is less than Vₐ. Thus, the output of the faulty signal output terminal corresponding to the comparator 3 is maintained in a low level (L), which indicates that the LED 1 acts as a short circuit. That is to say, it can be discriminated that whether the LED 1 is operated in a normal situation or acts as a short circuit in accordance with the voltage level outputted by the faulty signal output terminal corresponding to the comparator 3.

FIG. 2 illustrates another conventional circuit for detecting faulty diode disclosed in Taiwanese Patent No. I299405, issued in Aug. 1, 2008 entitled as “Method and Apparatus for Silent Current Detection”. The circuit for detecting faulty diode comprises a plurality of LEDs 10 connected in series (thereinafter is referred as LED series 10), a comparator 30 and a transistor 20. Wherein the anode of the LED series 10 is connected to a fixed voltage power supply V_{LED}; the source of the transistor 20 is grounded and the drain of the transistor 20 is connected to the cathode of the LED series 10; the positive terminal of the comparator 30 is applied with a reference voltage V_{cc}; the negative terminal of the comparator 30 is connected to the drain of the transistor 20. In this example, the transistor 20 serves as a driving control circuit and the drain of the transistor 20 is the controlled-output of the driving control circuit.

In accordance with preceding descriptions, the technological features of the prior art are to utilize the comparator for detecting faulty diode.

### SUMMARY OF THE INVENTION

The objects of the present invention are to provide a circuit for detecting faulty diode that has a differential amplifier used to discriminate whether the diode (such as LED that are connected to the circuit) is fail or acts in a normal situation by the way of investigating whether or not that the differential amplifier can constitute a feedback path.

One aspect of the present invention, a circuit for detecting faulty diode is disclosed, wherein the circuit for detecting faulty diode comprises a diode having an anode connected to a voltage supply; a resistor having a first end connected to a cathode of the diode; a transistor having a drain connected to a second end of the resistor and a source that is grounded; a differential amplifier having a positive terminal connected to the drain of the transistor, a negative terminal connected to a reference voltage input terminal for receiving a reference voltage, and an output terminal connected to a gate of the transistor; and a buffer having an input terminal connected to the gate of the transistor and a signal output terminal used to output a faulty signal.

To illustrate the make and use of the present invention, there provides several embodiments and the accompanying drawings. However, it must be appreciated that, the embodiments and drawings are illustrative but not intended to limit the scope of the present invention.

### BRIEF DESCRIPTION OF THE DRAWINGS

The above objects and advantages of the present invention will become more readily apparent to those ordinarily skilled in the art after reviewing the following detailed description and the accompanying drawings, in which:

FIG. 1 illustrates a conventional circuit for detecting faulty diode in accordance with the prior art.

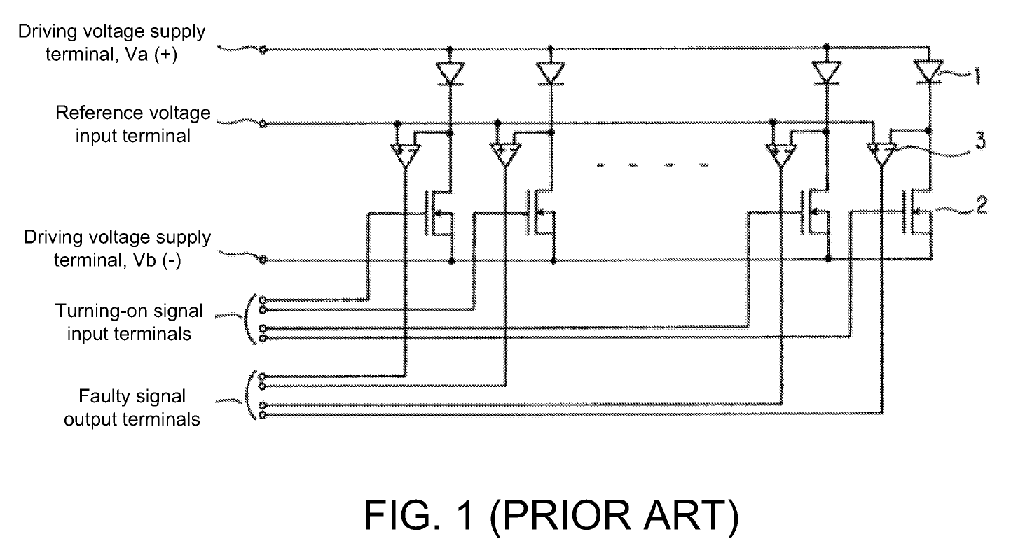

FIG. 2 illustrates another conventional circuit for detecting faulty diode in accordance with the prior art.

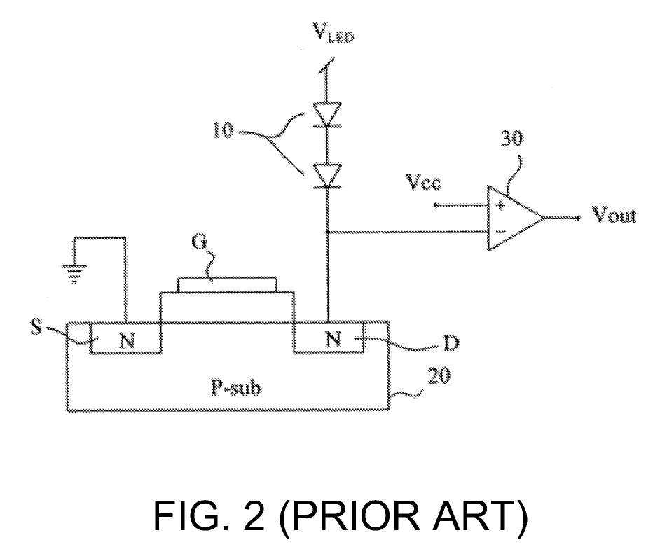

FIG. 3 illustrates a circuit for detecting faulty diode in accordance with one embodiment of the present invention.

### DETAILED DESCRIPTION OF PREFERRED EMBODIMENTS

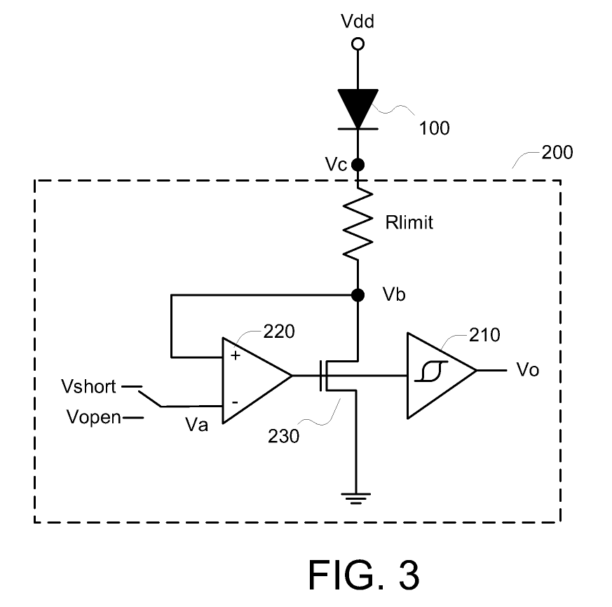

FIG. 3 illustrates a circuit for detecting faulty diode 200 in accordance with one embodiment of the present invention. Wherein the circuit for detecting faulty diode 200 comprises a current limited resistor Rₗᵢₘᵢₜ, a differential amplifier 220, a transistor 230 and a hysteresis buffer 210. In the present embodiment, an LED 100 is connected to the circuit for detecting faulty diode 200, wherein the LED 100 has an anode connected to a voltage supply V_{dd} and a cathode connected to a first end of the current limited resistor Rₗᵢₘᵢₜ; the transistor 230 has a drain connected to a second end of the current limited resistor Rₗᵢₘᵢₜ and a source that is grounded; the differential amplifier 220 has a positive terminal connoted to the drain of the transistor 230, a negative terminal selectively either connected to a short-testing terminal Vₛₕₒᵣₜ or connected to an open-testing terminal Vₒₚₑₙ, and an output terminal connected to the gate of the transistor 230 and further connected to an input terminal of the hysteresis buffer 210 from which a faulty signal can be outputted to discriminate whether the LED is fail or acts in a normal situation.

In some embodiments of the present invention, the voltage provided by the voltage supply V_{dd} is 5V, the forward bias of the LED 100 is 3.5V, the voltage (short-testing voltage) applied to the short-testing voltage terminal Vₛₕₒᵣₜ is 2.5V, and the voltage (open-testing voltage) applied to the open-testing voltage terminal Vₒₚₑₙ is 0.3V.

During an open-testing period, the negative terminal of the differential amplifier 220 is selected to connect with the open-testing terminal Vₒₚₑₙ to receive a voltage Vₐ of 0.3V. When the LED 100 is operated in a normal situation, the voltage V_{c} applied on the first end of the current limited resistor Rₗᵢₘᵢₜ is 1.5V (V_{c}=5V−3.5V=1.5V); and then a feedback path is constituted, whereby the voltage V_{b} applied on the drain of the transistor 203 is equal to Vₐ of 0.3V; the voltage outputted by the output terminal of the differential amplifier 220 is approximately close to the voltage provided by the voltage supply V_{dd}; and then the hysteresis buffer 210 outputs a high level signal Vₒ. It means that, when the signal Vₒ outputted by the hysteresis buffer 210 is maintained in a high level, the LED 100 is operated in a normal situation. On the other hand, when the LED 100 is open, the first end of the current limited resistor Rₗᵢₘᵢₜ is also open, whereby the feedback path can not be constituted. Thus, the voltage V_{b} is not equal to Vₐ of 0.3V, the voltage outputted by the output terminal of the differential amplifier 220 is approximately close to the grounding voltage, and then the hysteresis buffer 210 outputs a low level signal Vₒ. It means that, when the signal Vₒ outputted by the hysteresis buffer 210 is maintained in a low level, the LED 100 is open.

During a short-testing period, the negative terminal of the differential amplifier 220 is selected to connect with the short-testing terminal Vₛₕₒᵣₜ to receive a voltage Vₐ of 2.5V. When the LED 100 is operated in a normal situation, the voltage V_{c} applied on the first end of the current limited resistor Rₗᵢₘᵢₜ is 1.5V (V_{c}=5V−3.5V=1.5V), whereby a feedback path can not be constituted. Thus, the voltage V_{b} applied on the drain of the transistor 203 is not equal to Vₐ of 2.5V; the voltage outputted by the output terminal of the differential amplifier 220 is approximately close to the grounding voltage; and then the hysteresis buffer 210 outputs a low level signal Vₒ. It means that, when the signal Vₒ outputted by the hysteresis buffer 210 is maintained in a low level, the LED 100 is operated in a normal situation. On the other hand, when the LED 100 is short, the voltage V_{c} applied on the first end of the current limited resistor Rₗᵢₘᵢₜ is 5V (Vc=5V−0V), and then a feedback path is constituted, whereby the voltage V_{b} is equal to Vₐ of 2.5V the voltage outputted by the output terminal of the differential amplifier 220 is approximately close to the voltage provided by the voltage supply V_{dd}; and then the hysteresis buffer 210 outputs a high level signal Vₒ. It means that, when the signal Vₒ outputted by the hysteresis buffer 210 is maintained in a high level, the LED 100 is short.

According to the aforementioned embodiments, the features of the present invention is to provide a circuit for detecting faulty diode that has a differential amplifier and a hysteresis buffer, wherein the differential amplifier is used to discriminate whether a feedback path is constituted or not, and then the consequence can be outputted as a signal by the hysteresis buffer to indicate whether the LED is faulty or acts in a normal situation.

As is understood by a person skilled in the art, it is intended to cover various modifications and similar arrangements included within the spirit and scope of the appended claims, the scope of which should be accorded the broadest interpretation so as to encompass all such modifications and similar structure.

What is claimed is:

1. A circuit for detecting faulty diode comprising:
a diode, having an anode connected to a voltage supply;
a resistor, having a first end connected to a cathode of the diode;
a transistor, having a drain connected to a second end of the resistor and a source that is grounded;
a differential amplifier, having a positive terminal connected to the drain of the transistor, a negative terminal connected to a reference voltage input terminal for receiving a reference voltage, and an output terminal connected to a gate of the transistor; and
a buffer, having an input terminal connected to a gate of the transistor, and a signal output terminal used to output a faulty signal.

2. The circuit for detecting faulty diode according to claim 1, wherein the resistor is a current limited resistor.

3. The circuit for detecting faulty diode according to claim 1, wherein the diode is a light emitting diode (LED).

4. The circuit for detecting faulty diode according to claim 1, wherein the buffer is a hysteresis buffer.

5. The circuit for detecting faulty diode according to claim 1, wherein the reference voltage is a short-testing voltage or an open-testing voltage.

6. The circuit for detecting faulty diode according to claim 5, wherein when the reference voltage is the short-testing voltage and the signal outputted by the buffer is maintained in a high level, the diode is shorted.

7. The circuit for detecting faulty diode according to claim 5, wherein when the reference voltage is the short-testing voltage and the signal outputted by the buffer is maintained in a low level, then the diode is operated in a normal situation.

8. The circuit for detecting faulty diode according to claim 5, wherein when the reference voltage is the open-testing voltage and the signal outputted by the buffer is maintained in a high level, then the diode is operated in a normal situation.

9. The circuit for detecting faulty diode according to claim 5, wherein when the reference voltage is the open-testing voltage and the signal outputted by the buffer is maintained in a low level, then the diode is opened.
